(19) United States
(12) Patent Application Publication
(10) Pub. No.: US 2012/0231578 A1
(43) Pub. Date: Sep. 13, 2012

(54) FABRICATING METHOD OF ORGANIC THIN FILM TRANSISTOR HAVING A HYDROPHOBIC LAYER

(75) Inventors: Liang-Hsiang Chen, Taichung City (TW); Ko-Pin Liao, Taipei City (TW); Jia-Chong Ho, Hsinchu County (TW)

(73) Assignee: INDUSTRIAL TECHNOLOGY RESEARCH INSTITUTE, Hsinchu (TW)

(21) Appl. No.: 13/479,285

(22) Filed: May 24, 2012

Related U.S. Application Data
(62) Division of application No. 12/699,827, filed on Feb. 3, 2010.

(30) Foreign Application Priority Data
Feb. 10, 2009 (TW) 98104175

(51) Int. Cl. H01L 51/40

(52) U.S. Cl. 438/99; 257/E51.006

(57) ABSTRACT

A fabricating method of an organic thin film transistor having a hydrophobic layer is provided. The organic thin film transistor including a gate, a gate insulator covering the gate, a source, a drain, an organic semiconductor layer, a hydrophobic layer and a protecting droplet. A hydrophobic region is formed by forming the hydrophobic layer on a surface of the source and a surface of the drain, respectively. Meanwhile, a hydrophilic region is formed on the organic semiconductor layer exposed by the hydrophobic layer. The protecting droplet is self-assemblingly formed on the organic semiconductor layer to protect the device characteristic by using the surface tension thereof.

### CROSS-REFERENCE TO RELATED APPLICATION

This application is a divisional application of and claims the priority benefit of U.S. application Ser. No. 12/699,827, filed on Feb. 3, 2010, now pending, which claims the priority benefit of Taiwan application serial no. 98104175, filed on Feb. 10, 2009. The entirety of each of the above-mentioned patent applications is hereby incorporated by reference herein and made a part of specification.

### BACKGROUND

1. Field of the disclosure

The present disclosure relates to a semiconductor device and a fabricating method thereof. More particularly, the present disclosure relates to an organic semiconductor device and a fabricating method thereof.

2. Description of Related Art

As organic semiconductor devices can be fabricated on a flexible plastic substrate or a thin metal substrate, it has the characteristics of being light, cheap, and flexible. Among the organic semiconductor devices, organic thin film transistor (OTFT) has become one of the most important devices both in the academic circle and among industrial researchers in technically advanced countries.

In the techniques of fabricating the OTFT, in order to prevent moisture, oxygen, and the like in the nature from damaging OTFT devices, the organic semiconductor layer is usually covered by a passivation layer upon fabrication of the electrode of the transistor and the organic semiconductor layer. The passivation layer thus increases the life time of the transistor device under long-term usage and the reliability of electrical characteristics.

Generally, in order for the passivation layer of the OTFT to be patterned for exposing the electrode to electrically connect an external power source, several methods have been proposed. One of the methods is to perform the patterning with a photolithographic and etching process, which the passivation layer is firstly formed on the OTFT and then photoresist is coated thereon. Next, the photoresist is patterned by the photolithographic and etching process. Thereafter, a dry-etching method is utilized to remove the passivation layer exposed by the patterned photoresist layer. Finally, after the patterned passivation layer has been formed, the remaining photoresist layer is removed. However, the steps of patterning the passivation layer with the aforementioned photolithographic and etching process are complicated, and incomplete etching often results in the etching step, such that the devices are unstable.

Another method is to add a photosensitizer of dichromate directly into the resin material of the passivation layer, where the light beam passes through a patterned mask, so that the photosensitizer in the region radiated by the light beam in the passivation layer cross links with the resins. Here, as the region of resin material with cross linking is not soluble to the developer, patterning the passivation layer can be achieved. However, the dichromate that is added to the passivation layer as the photosensitizer is easily dissolved in water and diffuses quickly. As the dichromate is carcinogenic, when fabricating the passivation layer of the OTFT, the waste liquid is to be specifically recycled and specially disposed. Due to the rise of “environmental protection” awareness recently, the simplification of fabricating process, high material utility, and low pollution processing are becoming the main stream in the future. Hence, the problem of simplifying the processing procedure of the passivation layer of the OTFT while considering environmental protection has to be solved before the OTFT is industrialized.

### SUMMARY

One embodiment of the disclosure provides an organic thin film transistor (OTFT), where a passivation layer thereof is patterned according to a surface characteristic of underneath layer.

One embodiment of the disclosure provides an OTFT, which comprises a substrate, a gate, a gate insulator, a source, a drain, an organic semiconductor layer, a hydrophobic layer, and a protecting droplet. Herein, the gate is disposed on the substrate. The gate insulator covers the gate. The source and the drain are disposed respectively on the gate insulator above the two sides of the gate, and electrically insulated with the gate. The organic semiconductor layer is disposed between the source and the drain. The hydrophobic layer is disposed on the source and the drain, and exposes the organic semiconductor layer. A region covered by the hydrophobic layer is a hydrophobic region, and another region exposed by the hydrophobic layer is a hydrophilic region. Moreover, the protecting droplet covers the organic semiconductor layer.

One embodiment of the disclosure further provides a fabricating method of an OTFT, and the fabricating method includes the following steps: forming a gate and a gate insulator covering the gate on a substrate; forming a source and a drain respectively on the gate insulator above the two sides of the gate; forming a hydrophobic layer above the source and the drain, a region covered by the hydrophobic layer being a hydrophobic region and another region exposed by the hydrophobic layer being a hydrophilic region; forming an organic semiconductor layer between the source and the drain, the hydrophobic layer exposing the organic semiconductor layer; forming a liquid sealing material on the hydrophobic layer and the organic semiconductor layer, so as to condense a protecting droplet on the hydrophilic region.

The OTFT and the fabricating method thereof provided in the present disclosure change the surface characteristics of underneath layers by using the hydrophobic layer, such that the hydrophilic region is formed on the organic semiconductor layer, and the hydrophobic region is formed on the source and the drain. Next, the liquid sealing material is condensed on the organic semiconductor layer which is the hydrophilic region to form the protecting droplet due to the force of surface tension. Therefore, in one embodiment, it is possible to apply the fabricating method of the embodiment in the mass production of the OTFT, thereby may reducing the fabricating cost thereof.

In order to make the present disclosure more comprehensible, several embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIGS. 1A through 1E are cross-sectional views illustrating the steps of fabricating an OTFT according to an embodiment of the present disclosure.

FIG. 2 is a schematic top view of FIG. 1E.

### DESCRIPTION OF EMBODIMENTS

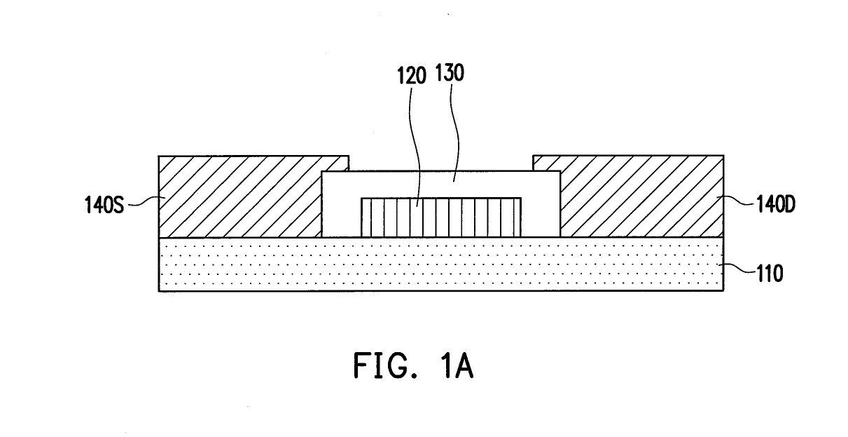

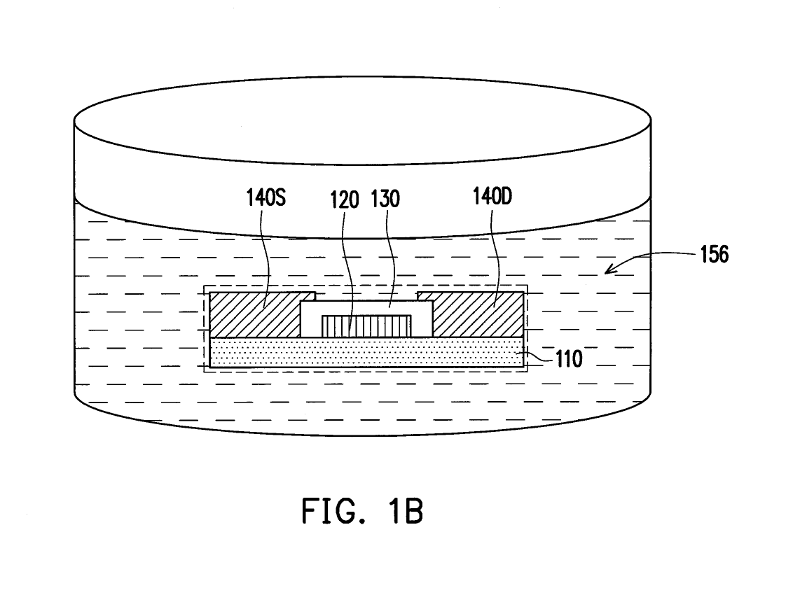

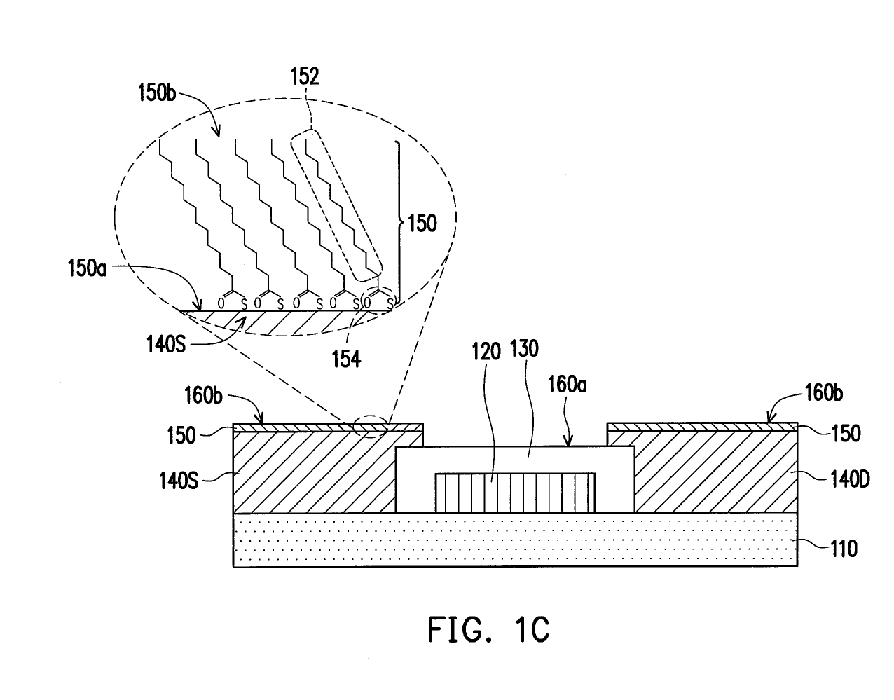

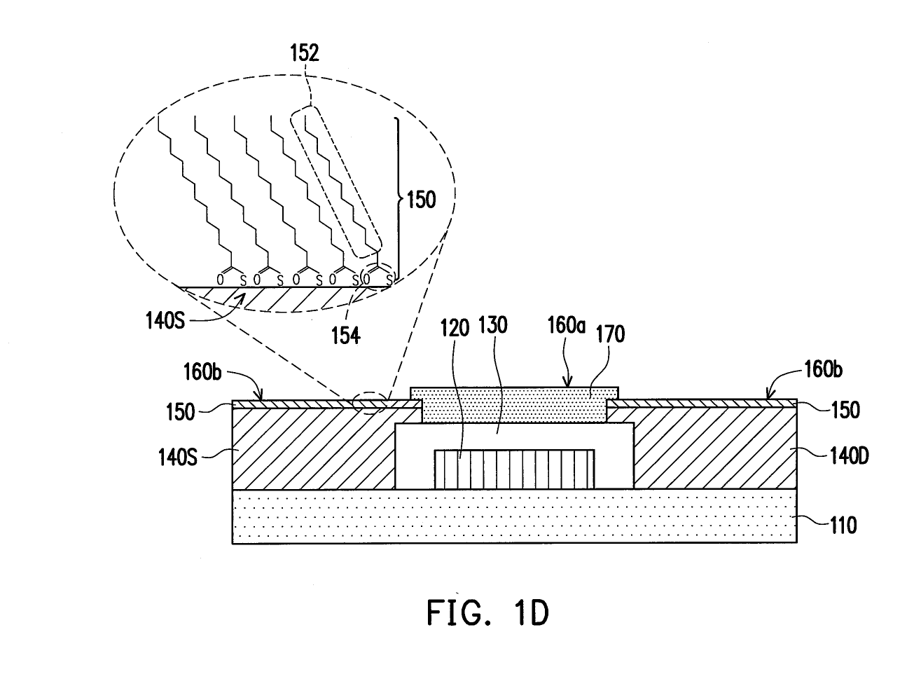

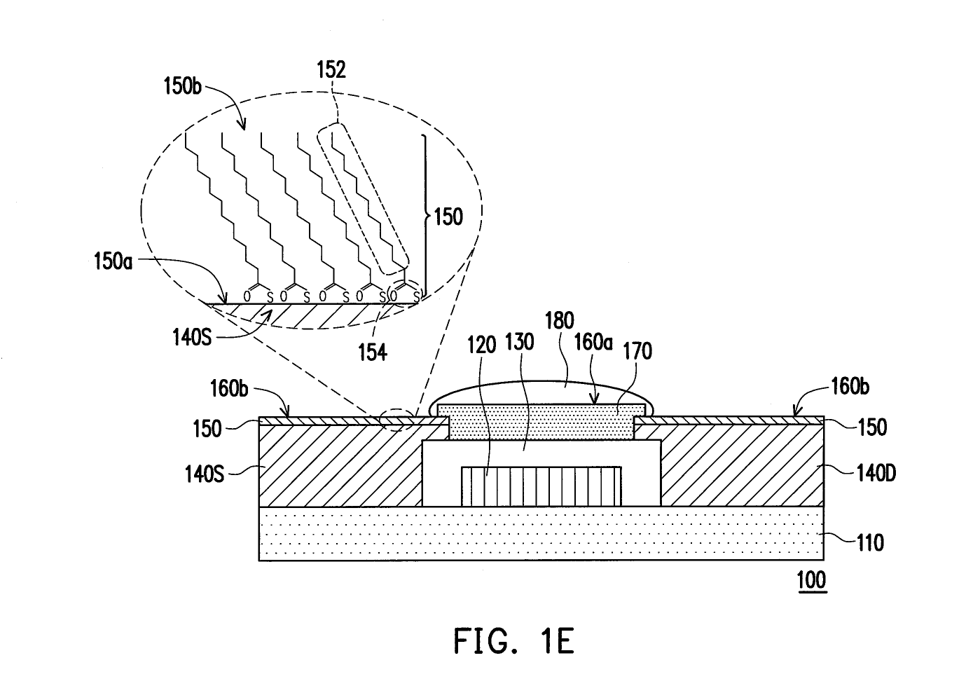

FIGS. 1A through 1E are cross-sectional views illustrating the steps of fabricating an OTFT according to an embodiment of the present disclosure.

Referring to FIG. 1A, a substrate 110 is provided, where the substrate 110 is a solid substrate such as a glass substrate, a quartz substrate, a silicon wafer, and the like, or a flexible substrate such as a plastic substrate, a metal thin film, and the like. Next, a gate 120 is formed on the substrate 110. The material of the gate 120 is, for example, silver oxide, silver alloy, gold alloy, copper alloy, aluminum alloy, or other suitable metals or metal alloys. The gate 120 is formed by performing a chemical vapor deposition (CVD) process or a physical vapor deposition (PVD) process.

Thereafter, referring to FIG. 1A, a gate insulator 130 is formed to cover the gate 120. The material of the gate insulator 130 is a silicon-containing compound, such as silicon oxide, silicon nitride, or other suitable silicon-containing dielectric layers. The gate insulator 130 is formed by performing the CVD process, for example. As shown in FIG. 1A, a source 140S and a drain 140D are respectively formed on the gate insulator 130 above the two sides of the gate 120. The material of the source 140S and the drain 140D is silver oxide, silver alloy, gold alloy, copper alloy, aluminum alloy, or other suitable metals or metal alloys. The source 140S and the drain 140D are formed by performing the CVD process or the PVD process.

Referring to FIG. 1B and FIG. 1C simultaneously, after the step of forming the source 140S and the drain 140D, a site selective hydrophobic layer 150 is formed on the surface of the substrate 110. The formation is illustrated in FIG. 1B. The method of forming the hydrophobic layer 150 includes: a hydrophobic solution 156 is firstly prepared. Then, the substrate 110 with the gate 120, the gate insulator 130, the source 140S, and the drain 140S formed thereon is soaked into the hydrophobic solution 156. Next, the hydrophobic layer 150 is formed on the surfaces of the source 1405 and the drain 140D as a spontaneous reaction of chemical adsorption is generated between the hydrophobic solution 156 and the source 140S and between the hydrophobic solution 156 and the drain 140D to change the physical characteristics (i.e. change in the hydrophobicity/hydrophilicity or the liquid contacting angle) of the surfaces of the source 140S and the drain 140D as illustrated in FIG. 1C. On the other hand, in the present embodiment, since the hydrophobic solution 156 does not generate the chemical adsorption reaction with the gate insulator 130, the hydrophobic layer 150 is not formed on the gate insulator 130. Thus, the hydrophobic layer 150 is capable of defining a hydrophilic region 160a and a hydrophobic region 160b spontaneously according to the different surface characteristics of different layers positioned thereunderneath. As shown in FIG. 1C, the surface characteristic of the hydrophobic layer 150 is hydrophobic, therefore, when the hydrophobic layer 150 is disposed on the source 140S and the drain 140D, the region covered by the hydrophobic layer 150 is the hydrophobic region 160b, and another region exposed by the hydrophobic layer 150 is the hydrophilic region 160a. In addition, the composition and the fabricating method of the hydrophobic solution 156 and the hydrophobic layer 150 are illustrated in the following.

The composition of the hydrophobic layer 150 usually includes long-chain thiol organic material, such as alkylthiol, dialkylthiol, acidic thiol, or the like. The method of fabricating the hydrophobic solution 156 may include the following steps. First, a long-chain thiol organic material, for example, alkylthiol, dialkylthiol, acidic thiol, or the like is added into the solvent (i.e. alcohol), then the organic material is mixed and diluted with the solvent according to volume ratio or molar ratio. Next, the organic material and the solvent are stirred thoroughly for use, here, the solvent is alcohol or an organic solvent and the molar ratio of the hydrophobic solution 156 is about 10⁻³M.

More specifically, the molecular material constituting the hydrophobic layer 150 includes, for example, a hydrophobic long-chain group 152 and a hydrophilic thiol group 154. The thiol group 154 is suitable for generating the chemical adsorption with the source 140S and the drain 140D, and the long-chain group 152 is suitable for changing the surface characteristic of the substrate 110.

In details, the long-chain group 152 is constituted by hydrocarbons arranged in a long-chain structure, or in functional groups such as the aromatic group, the pentafluoroaromatic group, the 4-nitroaromatic group, and the like. The hydrophobic layer 150 utilizes the Van der Waal's force between the molecules so that the long-chain groups 152 in the molecules are self-assembled and arranged into a monolayer film spontaneously. Overall, the monolayer film which is formed by molecules arranged in a single layer constitutes a hydrophobic surface. In order for the molecules to arrange orderly, the long-chain group 152 lacking side chains is preferable. Also, in the present embodiment, the material of the source 1405 and the drain 140D is silver oxide, for example, or silver alloy, gold alloy, copper alloy, or aluminum alloy. The thiol groups 154 in the molecules of the hydrophobic layer 150 generate the chemical adsorption with the source 1405 and the drain 140D self-assemblingly. Therefore, the hydrophobic layer 150 forms a chemical adsorption surface 150a on the contacting surface connected to the source 140S and the drain 140D, and constitutes a hydrophobic surface 150b, which is opposite to the chemical adsorption surface 150a, with the long-chain groups 152.

Next, referring to FIG. 1D, an organic semiconductor layer 170 is formed between the source 140S and the drain 140D, and the hydrophobic layer 150 is exposed. The material of the organic semiconductor layer 170 includes organic small molecules, organic polymers, or organic/inorganic mixture layers, such as pentacene, for instance. The organic semiconductor layer 170 is formed by performing a vacuum evaporation method, for example. As shown in FIG. 1D, a patterned organic semiconductor layer 170 is formed between the source 140S and the drain 140D. Thus, the organic semiconductor layer 170 exposes the hydrophobic layer 150. In the present embodiment, the step of forming the organic semiconductor layer 170 is performed after the step of forming the hydrophobic layer 150. Obviously, in another embodiment, the step of forming the organic semiconductor layer 170 can be performed before the step of forming the hydrophobic layer 150. At this time, although the substrate 110 with the gate 120, the gate insulator 130, the source 140S, the drain 140 D, and the organic semiconductor layer 170 formed thereon is soaked in the hydrophobic solution 156, the hydrophobic layer 150 merely forms on the source 140S and the drain 140D to expose the organic semiconductor layer 170. In other words, the present disclosure does not limit the formation order of the organic semiconductor layer 170 and the hydrophobic layer 150.

Subsequently, as illustrated in FIG. 1E, a liquid sealing material is formed on the substrate 110 to condense a protecting droplet 180 on the hydrophilic region 160a. In details, as the surface energies of the organic semiconductor layer 170 and that of the hydrophobic layer 150 are different, the surface on the substrate 110 can be divided into the hydrophobic region 160b and the hydrophilic region 160a. Thus, when the liquid sealing material is formed on the substrate 110, the liquid sealing material condenses into a protecting droplet 180 on the organic semiconductor layer 170 which is a hydrophilic region 160a by a force of surface tension. Therefore, the difference of surface energies of the organic semiconductor layer 170 and that of the hydrophobic layer 150 relates to the condensing speed and the condensing height of the liquid sealing material. The designer can adjust the material of the hydrophobic layer 150 and the organic semiconductor layer 170 suitably according to the thickness to be formed by the protecting droplet 180 or the concern regarding the fabricating production. The present disclosure is not limited thereto.

In particular, the liquid sealing material has free flow characteristics, when the liquid sealing material contacts the hydrophobic region 160b with a small surface energy, the liquid material flows toward the hydrophilic region 160a with a greater surface energy under repulsion. Moreover, under the surface tension, the liquid material has cohesive force and condenses to a hemisphere, and forms the protecting droplet 180 after the solvent has vaporized. The protecting droplet 180 is different from the film layer obtained from the conventional thin film deposition, and the thickness of the center of the protecting droplet 180 is greater than the thickness of the peripheral thereof. The composition and the fabricating method of the liquid sealing material is illustrated as follows.

The composition of the liquid sealing material usually includes hydrophilic material such as polyvinyl alcohol, which is mixed and diluted with the solvent based on the weight percentage or the molar ratio. Furthermore, the liquid sealing material can be used after thorough mixing. Here, the solvent may be selected from water or an organic solvent. In the present embodiment, the weight percentage of the liquid sealing material is about 2 wt. %. Thereafter, the liquid sealing material is coated on the hydrophobic layer 150 and the organic semiconductor layer 170 by a spin coating method.

After the liquid sealing material has been coated, a curing process is performed to form the protecting droplet 180. Here, the method of curing is an irradiation process or a heating process. Thereby, the fabrication of an OTFT 100 is initially completed. In the aforementioned fabricating method, the patterning process of the hydrophobic layer 150 and the protecting droplet 180 does not include the mask processing, but patterns the protecting droplet 180 simultaneously by using the chemical adsorption reaction and the surface characteristic of having different surface tensions between the materials. Hence, the OTFT 100 of the embodiment has the advantage of simplified fabricating process. In addition, different from prior art, the material used for the protecting droplet 180 is not added with dichromate, thus is more friendly to the environment. Besides, the protecting droplet 180 has the characteristics of high mechanical strength, chemical stability, and simple fabrication, so that the OTFT 100 of the embodiment is protected and the device characteristic is enhanced.

Next, the structure of the OTFT 100 provided by the present disclosure is illustrated hereinafter according to FIG. 1E depicting the embodiment.

Referring to FIG. 1E, the OTFT 100 is constituted by the substrate 110, the gate 120, the gate insulator 130, the source 140S, the drain 140D, the organic semiconductor layer 170, the hydrophobic layer 150, and the protecting droplet 180. Herein, the gate 120 is located on the substrate 110. The material of the substrate 110 is a solid substrate 110 or a flexible substrate 110, for example. The material of the gate 120 is silver oxide, silver alloy, gold alloy, copper alloy, aluminum alloy, or other suitable metals or metal alloys, for instance. Moreover, the gate insulator 130 covers the gate 120. The gate insulator 130 is a silicon-containing compound, such as silicon oxide, silicon nitride, or other suitable silicon-containing dielectric layers. The source 140S and the drain 140D are disposed respectively on the gate insulator 130 above the two side of the gate 120. The source 140S and the drain 140D are electrically insulated with the gate 120. Here, the material of the source 1405 and the drain 140D is silver oxide, silver alloy, gold alloy, copper alloy, aluminum alloy, or other suitable metals or metal alloys, for example. The organic semiconductor layer 170 is disposed between the source 140S and the drain 140D. The material of the organic semiconductor layer 170 includes, for example, organic small molecules, organic polymers, or organic/inorganic mixture layers.

Referring to FIG. 1E continuously, in the present disclosure, the hydrophobic layer 150 of the OTFT 100 is disposed above the source 140S and the drain 140D, and exposes the organic semiconductor layer 170. A region covered by the hydrophobic layer 150 is a hydrophobic region 160b, and another region exposed by the hydrophobic layer 150 is a hydrophilic region 160a. The material of the hydrophobic layer 150 includes the long-chain thiol organic material such as alkylthiol, dialkylthiol, or acidic thiol. In the present embodiment, the hydrophobic layer 150 forms a chemical adsorption surface 150a on the contacting surface connected to the source 1405 and the drain 140D, and constitutes a hydrophobic surface 150b, which is opposite to the chemical adsorption surface 150a, with the long-chain groups 152. In other words, the surface of the organic semiconductor layer 170 is a hydrophilic region 160a, and the region of the hydrophobic layer 150 covered on the source 140S and the drain 140D is a hydrophobic region 160b.

As shown in FIG. 1E, the OTFT 100 of one embodiment has the protecting droplet 180 to cover the organic semiconductor layer 170. The material of the protecting droplet 180 includes hydrophilic material such as polyvinyl alcohol and the like. Here, the surface energies of the underneath layers are different, such that the protecting droplet 180 is condensed on the organic semiconductor layer 170 which is a hydrophilic region 160a.

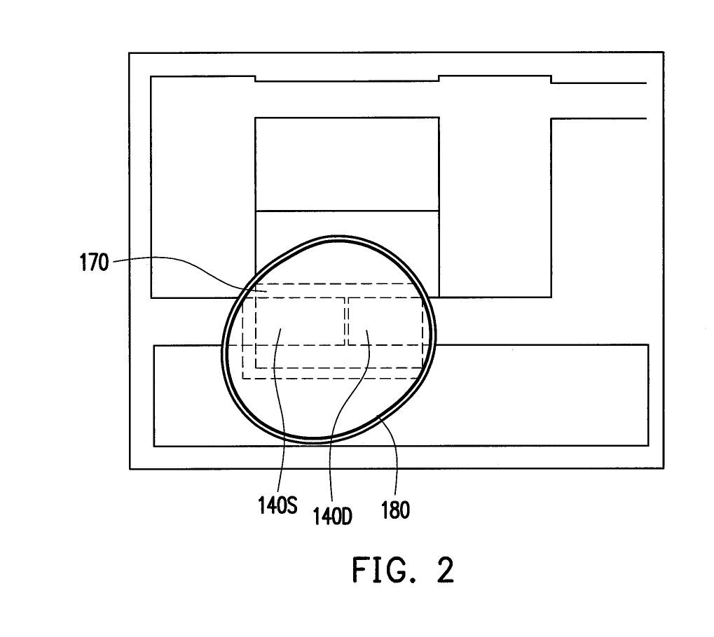

FIG. 2 is a schematic top view of FIG. 1E. Referring to FIG. 2, the protecting droplet 180 covers the organic semiconductor layer 170 with a hemispherical method. The organic semiconductor layer 170 is located within the coverage of the protecting droplet 180 to protect the device characteristic of the OTFT 100. In addition, as the protecting droplet 180 applies the surface tension to condense spontaneously above the organic semiconductor layer 170, the edge of the protecting droplet 180 forms an annular interface as illustrated in the figure. On the other hand, the protecting droplet 180 merely forms on the organic semiconductor layer 170 to expose the source 1405 and the drain 140D such that the processing of the subsequent fabrication of external conducting wire is facilitated.

In summary, the OTFT and the method of fabricating thereof in one embodiment of the present disclosure have at least the following features:

1. In one embodiment, the hydrophobic layer is formed for the substrate surface to obtain site selectivity, so that the hydrophilic region and the hydrophobic region are formed. Moreover, the protecting droplet is spontaneously formed on the organic semiconductor layer belonging to the hydrophilic region through the surface tension.

2. In one embodiment, the protecting droplet avoids the use of dichromate, which has a serious damaging effect on the environment, so the device characteristic can be enhanced in a more environmental friendly way.

3. In one embodiment, the passivation layer is not fabricated with the thin film deposition method or the photolithographic and etching process, so the fabricating method is cost-saving. The embodiment allows rapid mass production of the OTFT for reducing the fabricating cost thereof.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method of fabricating an organic thin film transistor, comprising:
forming a gate and a gate insulator covering the gate on a substrate;
forming a source and a drain respectively on the gate insulator above two sides of the gate;
forming a hydrophobic layer above the source and the drain, wherein a region covered by the hydrophobic layer is a hydrophobic region and another region exposed by the hydrophobic layer is a hydrophilic region;
forming an organic semiconductor layer between the source and the drain and exposing the hydrophobic layer; and
forming a liquid sealing material on the hydrophobic layer and the organic semiconductor layer so as to condense a protecting droplet on the hydrophilic region.

2. The method of fabricating the organic thin film transistor as claimed in claim 1, wherein the method of forming the hydrophobic layer above the source and the drain comprises:
preparing a hydrophobic solution;
soaking the substrate with the gate, the gate insulator, the source, and the drain formed thereon in the hydrophobic solution; and
generating a chemical adsorption between molecules in the hydrophobic solution and the source and between molecules in the hydrophobic solution and the drain to constitute a chemical adsorption surface of the hydrophobic layer, and forming a hydrophobic surface of the hydrophobic layer between the molecules in the hydrophobic solution through the Van der Waal's force.

3. The method of fabricating the organic thin film transistor as claimed in claim 2, wherein molecules in the hydrophobic solution has a long-chain group and a thiol group, molecules in the hydrophobic solution arrange into the hydrophobic surface with the long-chain group thereof, and the hydrophobic layer forms the chemical adsorption surface respective with the source and the drain through the thiol group.

4. The method of fabricating the organic thin film transistor as claimed in claim 1, wherein the hydrophobic layer is a self-assembled monolayer film.

5. The method of fabricating the organic thin film transistor as claimed in claim 1, wherein a composition of the hydrophobic layer comprises alkylthiol, dialkylthiol, acidic thiol, or long-chain thiol organic material.

6. The method of fabricating the organic thin film transistor as claimed in claim 1, wherein a method of forming the organic semiconductor layer comprises performing a vacuum evaporation method.

7. The method of fabricating the organic thin film transistor as claimed in claim 1, wherein the method of forming the protecting droplet comprises:
preparing the liquid sealing material with polyvinyl alcohol, wherein a content of polyvinyl alcohol is substantially 2 wt. %; and
coating the liquid sealing material on the hydrophobic layer and the organic semiconductor layer with a spin coating method, wherein the liquid sealing material condenses into a hemisphere on the organic semiconductor layer to form the protecting droplet.

8. The method of fabricating the organic thin film transistor as claimed in claim 1, wherein the step of forming the organic semiconductor layer is performed after the step of forming the hydrophobic layer.

9. The method of fabricating the organic thin film transistor as claimed in claim 1, wherein the step of forming the organic semiconductor layer is performed before the step of forming the hydrophobic layer, and the hydrophobic layer is only formed on the source and the drain.
